(19) United States
(12) Patent Application Publication
(10) Pub. No.: US 2020/0354834 A1
(43) Pub. Date: Nov. 12, 2020

(54) METHODS OF AREA-SELECTIVE ATOMIC LAYER DEPOSITION

(71) Applicant: International Business Machines Corporation, Armonk, NY (US)

(72) Inventors: Ekmini A. De Silva, Slingerlands, NY (US); Noel Arellano, Freemont, CA (US); Gregory M. Wallraff, San Jose, CA (US); Rudy J. Wojtecki, San Jose, CA (US)

(21) Appl. No.: 16/406,098

(22) Filed: May 8, 2019

(51) Int. Cl. C23C 16/455; H01L 21/02; C23C 16/04; C23C 16/40

(52) U.S. Cl. CPC C23C 16/45553; H01L 21/0228; H01L 21/02178; C23C 16/403; C23C 16/45527; C23C 16/04; C23C 16/45544

(57) ABSTRACT

A method is described for selectively forming alumina film layers on a silicon oxide surface by atomic layer deposition (ALD) in the presence of a metal-containing surface when each surface is exposed to the ALD reactants (i.e., a blocking layer is not used to prevent ALD reactants from contacting the metal-containing layer). Also described are methods of determining conditions for area-selective atomic layer deposition (AS-ALD) on a substrate containing two or more different surface materials using a database of ALD reactions.

### BACKGROUND

The present invention relates to methods of area-selective atomic layer deposition (AS-ALD), more specifically to the AS-ALD of alumina (Al₂O₃) on silicon oxide (SiO₂).

As the miniaturization of semiconductor technology continues, the need for deposition techniques that offer atomic level resolution has become increasingly important.

Chemical vapor deposition (CVD) is a chemical process designed to produce high-performance solid materials used in semiconductor processing. Typically, CVD techniques expose a substrate to one or more volatile precursors that decompose and/or react on the surface of the substrate to produce the deposited material. By-products may be produced and, subsequently, removed via gas flow through the reaction chamber. As non-limiting examples, CVD may be used to deposit layers of polysilicon, SiO₂, Si₃N₄, SiNH, HfO₂, Mo, Ta, Ti, TiN and W.

Atomic layer deposition (ALD) is another thin film deposition technique. ALD involves the use of precursors (chemicals) that react with the surface separately in a sequential manner. A thin film is grown by repeatedly exposing the precursors to the substrate. While similar in chemistry to CVD, ALD breaks the film-forming process into two or more sequential reactions, delivering the precursors of the ALD-formed material in separate steps to the substrate. ALD enables atomic scale deposition control and can achieve growth on the order of one monolayer or less per cycle. Separation of the precursors may be obtained by utilizing a purge gas (e.g., N₂, Ar) after each precursor to remove excess precursor from the process chamber and reduce or prevent parasitic CVD processes (e.g., extra deposition on the substrate via CVD). Fundamentally, this technique takes advantage of substrate surface groups that bind with organometallic precursors, thereby forming bound forms of the organometallic materials. In a separate step the bound organometallic materials are treated with water, ozone, and/or oxygen, thereby forming metal oxide bound to the substrate surface. As non-limiting examples, ALD may be used to deposit layers of Al₂O₃, TiO₂, SnO₂, ZnO, HfO₂, TiN, TaN, WN, NbN, Ru, Ir, Pt and ZnS.

Increasingly important are area-selective ALD processes (AS-ALD), which deposit film-forming precursors substantially or wholly in a desired pattern or location of the substrate. By controlling the area where these metals/metal oxides are deposited, the number of lithography, processing and etching steps can be reduced, thereby making this process highly sought by semiconductor manufacturers.

Conventional lithographic materials (such as patternable polymers) have been used to block (inhibit) surface reaction sites in ALD processes. Even thinner blocking layers have been demonstrated using self-assembled monolayers (SAMs) that show high levels of selectivity. However, these methods are disadvantaged by requiring additional processing steps associated with patterning and removing the blocking layer, and additionally long deposition times.

A specific need exists for depositing alumina (Al₂O₃) more efficiently on silicon oxide (SiO₂) surfaces in the presence of copper metal surfaces without utilizing blocking layers.

### SUMMARY

Accordingly, a method is disclosed, comprising:

providing a substrate comprising a silicon dioxide surface and a zero valent metal-containing surface; and

forming a layered structure comprising a layer of alumina selectively disposed on the silicon dioxide surface relative to the metal-containing surface using an atomic layer deposition (ALD) process, the process comprising one or more cycles of i) contacting the silicon dioxide surface and the metal-containing surface of the substrate with an organoaluminum compound at a temperature between 0° C. and 100° C., thereby forming a treated substrate and ii) contacting the treated substrate with water, thereby forming the layered structure.

Another method is disclosed, comprising:

providing a database of performed atomic layer deposition (ALD) reactions, the ALD reactions including successes and failures depositing target compositions on different substrate surfaces;

selecting a target composition to be formed by ALD;

selecting a target material on which to selectively deposit the target composition by ALD;

selecting a non-target material on which deposition by ALD of the target composition is not desired;

determining from the database i) common ALD conditions for ALD reactions that form the target composition on the target material and ii) ALD reactions that do not form the target composition on the non-target material; and

depositing the target composition by ALD on a substrate using the common ALD conditions, the substrate comprising i) target surface regions containing the target material and ii) non-target surface regions containing the non-target material, thereby forming a modified substrate comprising the target composition substantially or wholly disposed on the target surface regions.

Also disclosed is computer program product, comprising a computer readable hardware storage device having a computer-readable program code stored therein, said program code configured to be executed by a processor of a computer system to implement a method comprising:

providing a database of performed atomic layer deposition (ALD) reactions, the ALD reactions including successes and failures depositing target compositions on different substrate surfaces;

selecting a target composition to be formed by ALD;

selecting a target material on which to selectively deposit the target composition by ALD;

selecting a non-target material on which deposition by ALD of the target composition is not desired;

determining from the database common ALD conditions for ALD reactions that form the target composition on the target material and ALD reactions that do not form the target composition on the non-target material; and

depositing the target composition by ALD on a substrate comprising target surface regions containing the target material and the non-target surface regions containing non-target material using the common ALD conditions, thereby forming a modified substrate comprising the target composition substantially or wholly disposed on the target surface regions.

Further disclosed is a system comprising one or more computer processor circuits configured and arranged to:

provide a database of performed atomic layer deposition (ALD) reactions, the ALD reactions including successes and failures depositing target compositions on different substrate surfaces;

select a target composition to be formed by ALD;

select a target material on which to selectively deposit the target composition by ALD;

select a non-target material on which deposition by ALD of the target composition is not desired;

determine from the database common ALD conditions for ALD reactions that form the target composition on the target material and ALD reactions that do not form the target composition on the non-target material; and

deposit the target composition by ALD on a substrate comprising target surface regions containing the target material and the non-target surface regions containing non-target material using the common ALD conditions, thereby forming a modified substrate comprising the target composition substantially or wholly disposed on the target surface regions.

Also disclosed is a method, comprising:

providing a substrate that includes (i) a first portion made of zero-valent copper and (ii) a second portion made of silicon oxide having -OH groups attached thereto;

contacting the first portion and the second portion with a compound that includes aluminum (Al) for a predetermined first period of time at a temperature less than 100° C., thereby forming a treated substrate comprising a layer of aluminum-containing material substantially or wholly disposed on, and bound to, the second portion of the substrate, the compound being substantially non-reactive with the copper during the first period;

removing any of the compound that is not bound to the treated substrate;

introducing water to the treated substrate for a predetermined second period, thereby forming an Al₂O₃ layer substantially or wholly disposed on the second portion; and repeating the steps of contacting, removing, and introducing a given number of times, thereby forming additional layers of Al₂O₃ over the second portion of the substrate, wherein said given number is selected to avoid build-up of Al-containing compounds on the first portion of the substrate.

The above-described and other features and advantages of the present invention will be appreciated and understood by those skilled in the art from the following detailed description, drawings, and appended claims.

### BRIEF DESCRIPTION OF THE SEVERAL VIEWS OF THE DRAWINGS

FIG. 1 is a schematic of the disclosed process of area-selective deposition of aluminum oxide on a silicon dioxide surface, which takes advantage of the native reactivity difference of Cu surfaces at low temperature ALD cycles.

FIG. 2 is a flow diagram of a method of choosing conditions for area-selective ALD that utilizes a database of performed ALD reactions.

FIG. 3 is a block diagram showing a structure of a computer system and computer program code that may be used to implement a method of processing, including natural-language processing, to implement a method of area-selective ALD.

FIG. 4 is a graph showing XPS data of the Cu surface of Example 1 at different number of ALD cycles. Example 1 samples have SAMs on the Cu surface. Surface oxygen concentration of the copper surface is constant up to 40 cycles, after which a continuous increase is observed.

FIG. 5 is a graph showing XPS data of the SiO₂ surface of Example 1 at different numbers of ALD cycles.

FIG. 6 is a graph showing XPS data of the copper surface of Example 2 at different numbers of ALD cycles. Samples of Example 2 have no SAM blocking layer on the Cu surface.

FIG. 7 is a graph showing XPS data of the chromium surface of Example 3 at different numbers of ALD cycles. Samples of Example 2 have no SAM blocking layer on the copper surface.

FIG. 8 is a graph showing XPS data of the cobalt surface of Example 4 at different numbers of ALD cycles. Samples of Example 4 have no SAM blocking layer on the cobalt surface.

### DETAILED DESCRIPTION

Methods are disclosed for low temperature area-selective ALD of an alumina film layer. The substrate for the disclosed methods comprises two or more compositionally different surface regions. A first region (first portion) of a substrate surface contains silicon oxide. A second region (second portion) has a surface containing a zero-valent metal, where the second portion can have 0% up to about 20% native oxide of the metal in contact with an atmosphere. ALD deposition of a target composition is desired on the first regions, designated target surfaces. No deposition is desired on the second regions, designated non-target surfaces. The disclosed methods deposit alumina selectively on the first regions without using a blocking layer on the second regions to protect the metal-containing surface during the ALD.

Also disclosed is a computer method for choosing materials and conditions for selectively forming a film layer by ALD on a target surface of a substrate without using blocking layer(s) on non-target surface area(s) of the substrate. The ALD conditions are chosen utilizing a database of ALD reactions and a computer program for accessing the database. The computer program can also operate the ALD apparatus using the selected materials and conditions. A computer system for area-selective ALD film formation can comprise the database of ALD reactions, computer program for accessing the database, the ALD apparatus, a computer program operating the ALD apparatus, and associated display, communications, network, and electronic storage devices of the system.

An ALD cycle is typically conducted in a step-wise manner by i) contacting a gaseous first reactant with the substrate, thereby forming a first treated substrate, ii) purging excess first reactant using an inert gas (e.g., argon, nitrogen), iii) contacting a gaseous second reactant with the first treated substrate, thereby forming a second treated substrate, and iv) purging the excess second reactant, thereby forming a modified substrate comprising a monolayer of the target composition disposed on the target surface, the non-targeted surfaces being free of, or substantially free of, the ALD-formed target composition. Herein, an ALD cycle can comprise two or more sequential stages, each stage involving a different reactant used to make a target composition.

An ALD cycle can take from about 0.1 seconds to about 10 minutes to complete. Each ALD cycle deposits another monolayer of the target composition on the previously deposited monolayer. The change in thickness of the ALD-formed film layer per cycle is referred to as the “growth per cycle” (GPC). The final thickness of the ALD-formed layer is controlled by the number of ALD cycles performed.

Herein, “silicon oxide” includes silicon dioxide (SiO₂) and tetravalent silicon species bonded to one or more hydroxyl groups (i.e., —OH groups) such as, for example:

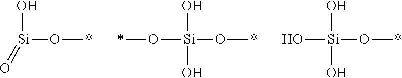

Metal-containing surfaces can comprise zero valent and/or ionic forms of metals including beryllium, magnesium, calcium, strontium, barium, radium, aluminum, gallium, indium, thallium, germanium, tin, lead, arsenic, antimony, bismuth, tellurium, polonium, and metals of Groups 3 to 12 of the Periodic Table. Metals of Groups 3 to 12 of the Periodic Table include scandium, titanium, vanadium, chromium, manganese, iron, cobalt, nickel, copper, zinc, yttrium, zirconium, niobium, molybdenum, technetium, ruthenium, rhodium, palladium, silver, cadmium, lanthanum, cerium, praseodymium, neodymium, promethium, samarium, europium, gadolinium, terbium, dysprosium, holmium, erbium, thulium, ytterbium, lutetium, hafnium, tantalum, tungsten, rhenium, osmium, iridium, platinum, gold, mercury, actinium, thorium, protactinium, uranium, neptunium, plutonium, americium, curium, berkelium, californium, einsteinium, fermium, mendelevium, nobelium, lawrencium, rutherfordium, dubnium, seaborgium, bohrium, hassium, meitnerium, darmstadtium, roentgenium, and copernicium. In an embodiment, the metal-containing surface contains a metal selected from the group consisting of copper, chromium, and cobalt.

The disclosed methods do not require a blocking layer on non-target surface(s) to guide the adsorption of an ALD reactant to a target surface area of the substrate. Herein, a blocking layer is a temporary layer used on a non-target surface. The blocking layer is removed from the ALD-modified substrate after an ALD process. In an embodiment, the disclosed methods exclude the use of a blocking layer.

The ALD process can include an optional treatment (e.g., reducing step) between ALD cycles or after completing all of the ALD cycles that refreshes the surface properties of non-targeted surfaces of the substrate. As a non-limiting example, the non-target metal-containing surfaces can be treated with a reducing agent (e.g., hydrogen delivered by the ALD apparatus) in order to convert any oxidized metal of the non-targeted surfaces formed by exposure to water, ozone, and/or oxygen back to its pre-oxidized state (e.g., zero valent metal). The optional treatment preferably occurs without significantly altering the surface properties of the ALD-formed film layer on the target surface areas. The reducing step can also increase etch resistance of the ALD-deposited film layer in known etch processes used in lithography.

The ALD process can include an annealing step between ALD cycles and/or after an ALD process to effect a change in the physical and/or mechanical properties of the ALD-formed film layer (e.g., densifying the ALD film layer and/or increasing crystallinity). The ALD-formed layer can be annealed at the same temperature of the ALD deposition or a different temperature. The annealing step, if performed, can be conducted at a temperature of 0° C. to 500° C., more specifically 100° C. to 500° C., and even more specifically 200° C. to 400° C. by heating the ALD treated substrate under an inert atmosphere (i.e., argon, nitrogen). In an embodiment, the annealing step is performed at a temperature above 100° C.

Herein, an ALD process comprises one or more ALD cycles (i.e., one ALD cycle equals two ALD half-cycles) plus any optional treatments performed between ALD cycles. When film formation is favored, an ALD cycle can selectively generate a monolayer of ALD-formed film on a target surface without forming a film on a non-target surface of a substrate. An ALD process can comprise 1 to 100,000 ALD cycles, 1 to 10,000 ALD cycles, 1 to 1000 ALD cycles, or 1 to 100 ALD cycles.

A given ALD cycle can produce a monolayer of ALD-formed material (target composition) having a thickness of about 0.04 nm to about 0.10 nm. An ALD-formed film can comprise one or more monolayers of ALD-formed material. An ALD process can produce an ALD-formed film having a thickness of about 0.001 nm to about 1000 nm. A 40 cycle ALD process produces a film having a thickness of about 2.4 nm.

### Method 1

This method is a more specific method of selectively forming an alumina film on a silicon dioxide surface in the presence of a metal-containing surface. Area-selectivity occurs at a temperature between 0° C. and 100° C., which is not observed when the ALD process is performed at a typical temperature of about 200° C. or higher.

To illustrate, in the first half-cycle of an ALD process to form an area-selective alumina film on a silicon oxide surface, a volatile organoaluminum compound (e.g., trimethyl aluminum, triethyl aluminum), a precursor of alumina, is delivered by an ALD apparatus to a chamber containing a substrate. The precursor makes contact with the exposed surfaces of the substrate and selectively adsorbs to the silicon oxide surface regions forming an initial monolayer comprising adsorbed organoaluminum species. In a second half-cycle of the ALD process, water vapor, ozone, and/or oxygen are delivered by ALD to the substrate, converting the initial monolayer to alumina and releasing volatile side products (e.g., methane, methanol). Herein, the term “water” means H₂O, D₂O, or a combination thereof. Other proton donors can be used for converting the initial monolayer to alumina such as, for example alcohols (e.g., methanol, ethanol) and carboxylic acids (e.g., acetic acid).

Under these conditions, the alumina precursor in the first half-cycle selectively adsorbs to the silicon oxide surfaces in the presence of a metal-containing surface. The metal-containing surface preferably comprises copper, chromium, or cobalt, and area-selectivity is observed for at least 1 ALD cycle.

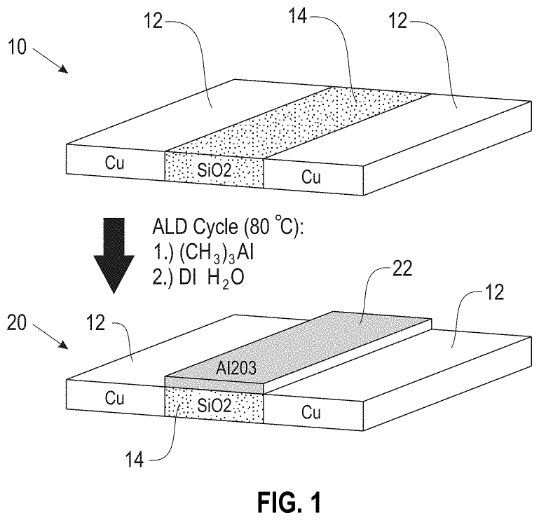

FIG. 1 illustrates the disclosed method using cross-sectional layer diagrams for a substrate comprising silicon oxide and copper-containing surfaces. The method comprises selecting a substrate 10 composed of target surface regions 14 containing silicon oxide (referred to herein as “silicon surfaces”) and non-target surface regions 12 containing copper and/or copper oxides (referred to herein as “copper surfaces”). The substrate 10 is initially flushed with an inert gas (e.g., argon, nitrogen) at a selected ALD temperature between 0° C. and 100° C., more specifically between 50° C. and 100° C., even more specifically between 60° C. and 90° C., and most specifically 75° C. to 85° C. for a period of 1 second to 10 minutes, more preferably 1 minute to 10 minutes, and most preferably 1 minute to 5 minutes. In a preferred embodiment, each ALD half-cycle is performed at the same ALD temperature. In the first ALD half-cycle the substrate is dosed (brought into contact) with an organoaluminum compound (e.g., trimethyl aluminum (TMA), triethylaluminum (TEA), referred to herein as alumina precursor) that deposits substantially or wholly on the silicon surfaces of the substrate, thereby forming an initial monolayer. The time of treatment of the alumina precursor with the substrate can be for a period of 1 second to 10 minutes, more preferably 1 minute to 10 minutes, and most preferably 1 minute to 5 minutes. The pressure of the alumina precursor can be 10⁻¹ torr to 10⁻⁵ torr, preferably about 10⁻² torr to 10⁻⁴ torr, most preferably about 10⁻³ torr.

In this instance, the initial monolayer comprises organoaluminum species that are covalently linked to one or two oxygens of the silicon surfaces (e.g., Me₂Al(O—*), MeAl(O—*)₂). The adsorption of precursor to the target surface can be by covalent or non-covalent binding. After formation of the initial monolayer, unbound organoaluminum precursor is purged from the ALD chamber using an inert gas (e.g., argon, nitrogen) optionally assisted by vacuum. This completes the first half-cycle. In the second half-cycle, the substrate containing the initial monolayer is treated with at least one second reactant (e.g., water vapor, oxygen, ozone, combinations the foregoing). The second reactant reacts with the adsorbed precursor, thereby forming layered structure 20 comprising an alumina monolayer film 22 disposed substantially or exclusively on first surface regions 14 (silicon surfaces). The time of treatment with the second reactant can be for a period of 1 second to 10 minutes, more preferably 1 minute to 10 minutes, and most preferably 1 minute to 5 minutes. The pressure of the second reactant can be 10⁻¹ torr to 10⁻⁵ torr, preferably about 10⁻² torr to 10⁻⁴ torr, most preferably about 10⁻³ torr. Another purge using an inert gas removes unreacted second reactant. In an embodiment, the second reactant is deionized water vapor. This completes the second half-cycle of an ALD cycle. In subsequent ALD cycles an alumina monolayer can be formed substantially or wholly on the alumina monolayer formed in the previous ALD cycle.

At the low ALD temperature, copper surfaces remain free of, or substantially free of, alumina for up to about 40 ALD cycles, chromium for up to about 3-5 ALD cycles, and cobalt up to about 10-15 ALD cycles. The growth rate of alumina on the silicon surfaces under these conditions is approximately 0.06 nm/cycle, indicating that the film grown on the silicon surface after 40 ALD cycles is about 2.4 nm in thickness.

The method is performed without using a blocking layer to protect the metal surfaces during the ALD cycles. In an embodiment, the method excludes a blocking layer on the copper surfaces. The copper surfaces have contact with each reactant of each ALD half-cycle.

The substrate can be maintained at a constant temperature for the entire ALD process. Alternatively, the temperature of the ALD chamber can be adjusted during the purging to assist in removal of excess reactants (alumina precursor, water vapor, oxygen).

Non-limiting uses of the layered structure formed by the above method include etch masks for lithographic processes and components of a semiconductor devices.

### Method 2

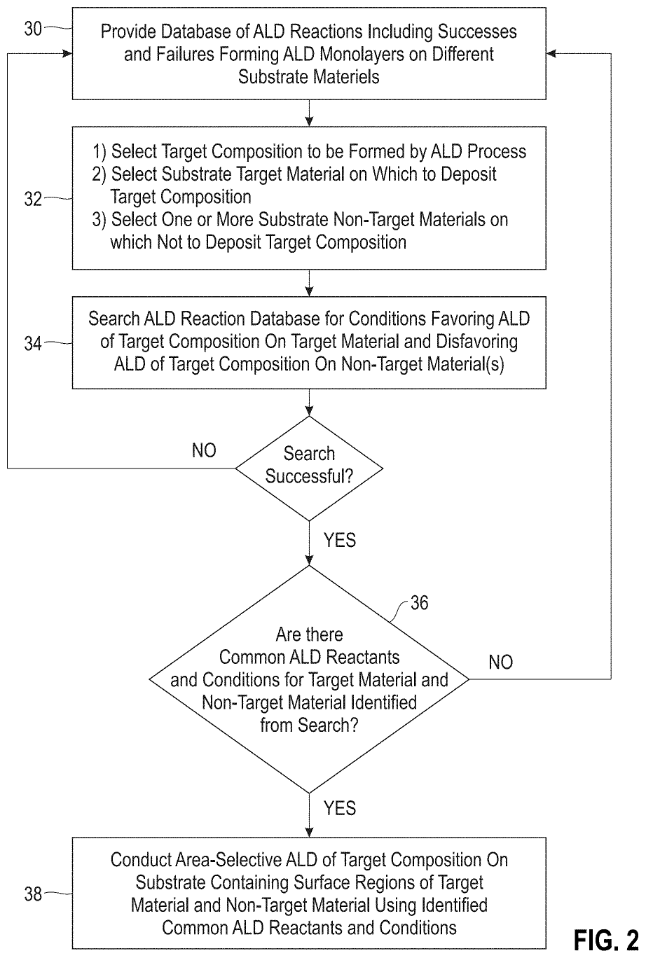

This method applies to any desired target composition of the ALD film layer (e.g., Al₂O₃) and is illustrated in the flow diagram of FIG. 2.

The method utilizes a database of ALD film-forming reactions (FIG. 2, box 30). A given record of the database includes ALD reactants, substrate materials, ALD device, ALD conditions, post-ALD analyses of substrate surfaces. The database can contain one or more data tables of ALD reactions, each data table comprising at least one record of an ALD film-forming reaction. Each record can include metadata associated with a given ALD reaction (e.g., date, time, origin of reactants, origin of substrate, treatment of the substrate prior to ALD, criteria for an acceptable monolayer, and the like). Criteria for an acceptable monolayer can be based, for example, on elemental analysis of the top surface, 3-dimensional characterization of the layer by atomic force microscopy, images of the layer obtained by scanning electron microscopy, and/or physical properties of the monolayer (e.g., thermal and electrical conductivity, resistivity, reflectivity, and the like).

The database includes successes and failures of ALD film-forming reactions. A success can mean an acceptable ALD monolayer of the target composition was formed by an ALD process on a given substrate material using a given set of reactants and a given set of ALD conditions. A success can also mean the elemental composition of the given substrate surface was changed an acceptable amount by an ALD process using the given set of reactants, the given substrate material, and the given set of ALD conditions. A failure can mean none of, or substantially none of, an ALD film layer of the target composition was formed on a given substrate material in an ALD process using a given set of reactants and a given set of ALD conditions. A failure can also mean the baseline elemental composition of the surface of the given substrate material remained unchanged, or substantially unchanged after an ALD process using the given set of reactants and the given set of ALD conditions.

Each record of the database preferably contains information pertinent to the results of one ALD process. Each record of the database includes the number of ALD cycles, the pre-ALD and post-ALD analyses of the surface materials of the substrate before the ALD process and a measure of the degree to which any change occurred in the surface composition of the substrate after the ALD process (e.g., percent change in oxygen content, percent change in a particular metal content).

Non-limiting ALD conditions include: substrate temperature during deposition of first reactant(s), first reactant(s) pressure, first reactant(s) flow rate, first reactant(s) deposition time, purge time of first reactant(s), purge gas of first reactant(s), purge temperature of first reactant(s), substrate temperature during deposition of second reactant(s), second reactant(s) pressure, second reactant(s) flow rate, second reactant(s) deposition time, purge time of second reactant(s), purge gas of second reactant(s), purge temperature of second reactant(s), optional annealing temperature, and optional annealing time.

Each record can also include properties of the ALD-formed film layer pertinent to its intended use (e.g., thermal and electrical conductivity, light absorption/transmittance/reflectance properties, magnetic properties, gas permeation properties, antimicrobial properties).

The ALD reaction data can be gathered by submitting different substrate materials in the form of coupons to a given ALD process, analyzing the changes to the surface of each coupon after 1 or more ALD cycles, and posting the results for each coupon as a separate record of the database. A given coupon can contain more than one substrate material arranged in a manner that allows for separate analyses of the different surfaces in a given ALD process, which can be posted as separate records in the database. In this manner, the database can be constructed to have hundreds, thousands, hundreds of thousands, even millions of ALD film-forming reactions using different reactants, substrate materials, and ALD conditions, including number of ALD cycles.

A computer-driven or manual search of the database can then be performed to identify ALD conditions favoring ALD film formation of a target composition (e.g., alumina) on a target surface of a substrate while disfavoring film formation on other non-target surface region(s)) of the substrate, without using an inhibiting layer or an activating layer to guide the deposition of ALD reactants.

In practice, this method comprises (FIG. 2, box 32): i) selecting a target composition (e.g., alumina) to be formed by an ALD process, ii) selecting a target material (e.g., silicon oxide) on which to deposit the target composition by ALD, and iii) selecting one or more non-target materials (e.g., copper) on which no ALD film formation is desired. These selected parameters become input for a search of the ALD reaction database to identify ALD reactants and ALD conditions favoring ALD film formation of the target composition on the target material and disfavoring ALD film formation on the non-target material (FIG. 2, box 34). As a non-limiting example, the search can identify a first reactant and a second reactant for forming an alumina film by ALD. The search can identify ALD conditions including but not limited to a range of temperatures, times of reactions, and number of ALD cycles for which alumina film formation using the identified reactants is favored on silicon oxide but not on copper metal.

If the search is not successful, additional ALD reactions can be conducted and entered into the database to fill gaps in the experimental conditions and results.

If the search is successful, the method further comprises (FIG. 2, 36) determining whether common ALD conditions exist within the reactions found that favor selective ALD deposition of the target composition on the target material and disfavor deposition of the target composition on the non-target material.

If common ALD conditions are obtained, then the ALD is performed using the identified first reactant, the identified second reactant, and the identified common ALD conditions with a substrate comprising surface areas containing the selected target material and other surface areas containing the non-target material, (FIG. 2, 38). The result is an ALD film comprising the ALD target composition selectively disposed on the target material of the substrate while leaving the non-target material(s) free of, or substantially free of, any ALD film disposed thereon.

The search can be restricted to a pre-defined first reactant and pre-defined second reactant of the ALD process for making the target composition. In this instance, the search output (e.g., ALD conditions) will be limited to those associated with the pre-defined reactants. Otherwise, the search output can include one or more potential first reactants and one or more potential second reactants along with their associated ALD conditions favoring deposition on the target surface and disfavoring deposition on the non-target surface.

### Substrates

The substrate can be a layered structure comprising one or more layers having a top surface. The substrate comprises target surface regions and non-target surface regions composed of different materials. The substrate, and more particularly the surface of the substrate, can comprise inorganic or organic materials such as metals, carbon, and/or polymers. More particularly, the substrate can comprise a semiconducting material including, for example, Si, SiGe, SiGeC, SiC, Ge alloys, GaAs, InAs, InP, silicon nitride, titanium nitride, hafnium oxide, as well as other III-V or II-VI compound semiconductors. The substrate can comprise a dielectric material such as, for example, SiO₂, TiO₂, Al₂O₃, Ta₂O₅ and polymers (e.g., polyimides, polamides, polyethylenes). The substrate can also comprise a layered semiconductor such as Si/SiGe, or a semiconductor-on-insulator (SOI). In particular, the substrate can contain a Si-containing semiconductor material (i.e., a semiconductor material that includes Si). The semiconductor material can be doped, non-doped or contain both doped and non-doped regions therein.

The substrate can have an anti-reflection control layer (ARC layer) or a bottom ARC layer (BARC layer) to reduce reflectivity of the film stack. Many suitable BARCs are known in the literature including single layer BARCs, dual layer BARCs, graded BARCs, and developable BARCs (DBARCs). The substrate can also comprise a hard mask, a transfer layer (e.g., planarizing layer, spin-on-glass layer, spin-on carbon layer), and other materials as required for the layered device.

The substrate can be an inflexible structure (e.g., silicon wafer) or a flexible structure (e.g., polyethylene sheet). The substrate can be 1-dimensional (e.g., wire), 2-dimensional (e.g., a wafer), or 3-dimensional (e.g., a bottle).

### Utility

Non-limiting applications of the disclosed methods include the fabrication of photovoltaic devices, integrated circuit (IC) chips, MEMS (Microelectromechanical systems) devices, FETs, displays, and storage devices. More specific layer applications include capping layers, gate dielectrics, spacers, liners, Cu caps, etch stops, hard masks, interlevel dielectrics (ILD), permanent layers, disposable layers for wet and reactive ion etching (RIE) selectivity, stop layers for chemical mechanical polishing (CMP), barrier layers, and through silicon via liner layers. Non-limiting end products for IC chips include toys, energy collectors, solar devices, and other applications including computer products or devices having a display, a keyboard or other input device, and a central processor. Photovoltaic devices can be particularly useful for solar cells, panels or modules employed to provide power to electronic devices, homes, buildings, vehicles, etc.

### Computer Hardware and Software

The computer system for implementing the present invention can take the form of an entirely hardware embodiment, an entirely software embodiment (including firmware, resident software, microcode, etc.), or a combination of software and hardware that may all generally be referred to herein as a “circuit,” “module,” or “system.”

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

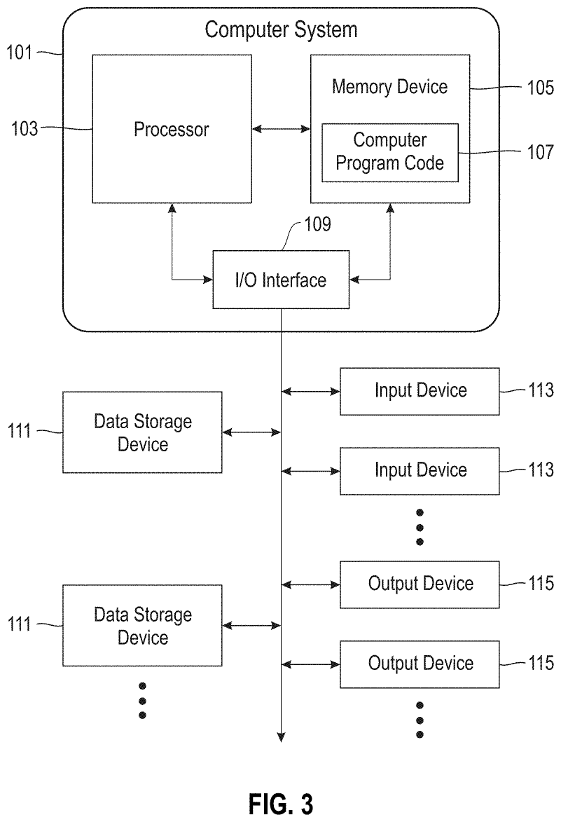

FIG. 3 shows a structure of a computer system and computer program code that may be used to implement a method of processing, including natural-language processing, to enter, search, retrieve, and report information contained in an ADL reaction database and perform other processes disclosed herein. In FIG. 3, computer system 101 comprises a processor 103 coupled through one or more I/O Interfaces 109 to one or more hardware data storage devices 111 and one or more I/O devices 113 and 115. Hardware data storage devices 111 can contain, for example, the ADL reaction database.

Hardware data storage devices 111 may include, but are not limited to, magnetic tape drives, fixed or removable hard disks, optical discs, storage-equipped mobile devices, and solid-state random-access or read-only storage devices. I/O devices may comprise, but are not limited to: input devices 113, such as keyboards, scanners, handheld telecommunications devices, touch-sensitive displays, tablets, biometric readers, joysticks, trackballs, or computer mice; and output devices 115, which may comprise, but are not limited to printers, plotters, tablets, mobile telephones, displays, or sound-producing devices. Data storage devices 111, input devices 113, and output devices 115 may be located either locally or at remote sites from which they are connected to I/O Interface 109 through a network interface.

Processor 103 may also be connected to one or more memory devices 105, which may include, but are not limited to, Dynamic RAM (DRAM), Static RAM (SRAM), Programmable Read-Only Memory (PROM), Field-Programmable Gate Arrays (FPGA), Secure Digital memory cards, SIM cards, or other types of memory devices.

At least one memory device 105 contains stored computer program code 107, which is a computer program that comprises computer-executable instructions. The stored computer program code can include a program for natural-language processing that implements the disclosed methods. The data storage devices 111 may store the computer program code 107. Computer program code 107 stored in the storage devices 111 can be configured to be executed by processor 103 via the memory devices 105. Processor 103 can execute the stored computer program code 107.

Thus the present invention discloses a process for supporting computer infrastructure, integrating, hosting, maintaining, and deploying computer-readable code into the computer system 101, wherein the code in combination with the computer system 101 is capable of performing the disclosed methods.

Any of the components of the present invention could be created, integrated, hosted, maintained, deployed, managed, serviced, supported, etc. by a service provider. Thus, the present invention discloses a process for deploying or integrating computing infrastructure, comprising integrating computer-readable code into the computer system 101, wherein the code in combination with the computer system 101 is capable of performing the disclosed methods.

One or more data storage units 111 (or one or more additional memory devices not shown in FIG. 3) may be used as a computer-readable hardware storage device having a computer-readable program embodied therein and/or having other data stored therein, wherein the computer-readable program comprises stored computer program code 107. Generally, a computer program product (or, alternatively, an article of manufacture) of computer system 101 may comprise said computer-readable hardware storage device.

While it is understood that program code 107 may be deployed by manually loading the program code 107 directly into client, server, and proxy computers (not shown) by loading the program code 107 into a computer-readable storage medium (e.g., computer data storage device 111), program code 107 may also be automatically or semi-automatically deployed into computer system 101 by sending program code 107 to a central server (e.g., computer system 101) or to a group of central servers. Program code 107 may then be downloaded into client computers (not shown) that will execute program code 107.

Alternatively, program code 107 may be sent directly to the client computer via e-mail. Program code 107 may then either be detached to a directory on the client computer or loaded into a directory on the client computer by an e-mail option that selects a program that detaches program code 107 into the directory.

Another alternative is to send program code 107 directly to a directory on the client computer hard drive. If proxy servers are configured, the process selects the proxy server code, determines on which computers to place the proxy servers' code, transmits the proxy server code, and then installs the proxy server code on the proxy computer. Program code 107 is then transmitted to the proxy server and stored on the proxy server.

In one embodiment, program code 107 is integrated into a client, server and network environment by providing for program code 107 to coexist with software applications (not shown), operating systems (not shown) and network operating systems software (not shown) and then installing program code 107 on the clients and servers in the environment where program code 107 will function.

The first step of the aforementioned integration of code included in program code 107 is to identify any software including the network operating system (not shown), which is required by program code 107 or that works in conjunction with program code 107 and is on the clients and servers where program code 107 will be deployed. This identified software includes the network operating system, where the network operating system comprises software that enhances a basic operating system by adding networking features. Next, the software applications and version numbers are identified and compared to a list of software applications and correct version numbers that have been tested to work with program code 107. A software application that is missing or that does not match a correct version number is upgraded to the correct version.

A program instruction that passes parameters from program code 107 to a software application is checked to ensure that the instruction's parameter list matches a parameter list required by the program code 107. Conversely, a parameter passed by the software application to program code 107 is checked to ensure that the parameter matches a parameter required by program code 107. The client and server operating systems, including the network operating systems, are identified and compared to a list of operating systems, version numbers, and network software programs that have been tested to work with program code 107. An operating system, version number, or network software program that does not match an entry of the list of tested operating systems and version numbers is upgraded to the listed level on the client computers and upgraded to the listed level on the server computers.

After ensuring that the software, where program code 107 is to be deployed, is at a correct version level that has been tested to work with program code 107, the integration is completed by installing program code 107 on the clients and servers.

Embodiments of the present invention may be implemented as a method performed by a processor of a computer system, as a computer program product, as a computer system, or as a processor-performed process or service for supporting computer infrastructure.

The following examples illustrate forming alumina on silicon oxide selectively in the presence of a copper layer, chromium layer, and cobalt layer using an ALD temperature of 80° C.

### EXAMPLES

### Preparation of Substrates

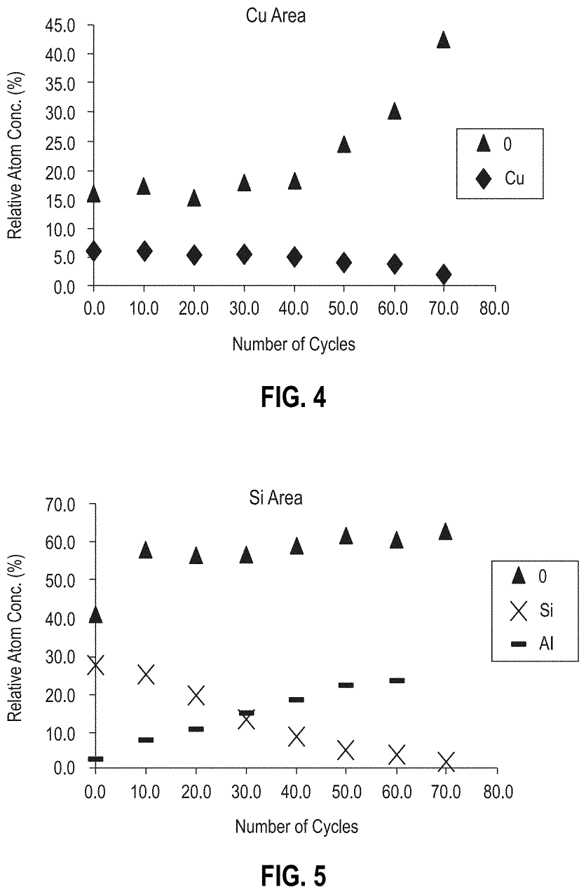

A 50 nm thick copper metal film was evaporated onto a four inch reclaimed silicon wafer using a circular shadow mask that protected a portion of the native SiO₂ surface from Cu deposition. The portion of the wafer on which the copper film was deposited had a chromium adhesion layer disposed on the silicon substrate. The native SiO₂ surface had a thickness of about 2 nm. The copper film was deposited at a pressure of 10⁻⁵ torr and had a surface native oxide content of about 17% (see FIG. 4 at 0 cycles). No treatments prior to ALD were performed on the wafers after thermal deposition of the copper.

### ALD Process

The following general procedure was used to treat sample substrates by ALD to form alumina films disposed on the substrate surface. Wafers containing both SiO₂ and Cu surfaces were broken up into coupons. A portion of the coupons contained a SAM on the Cu surface, another portion of the coupons contained no SAM. The individual coupons were loaded into an ALD chamber. The Al₂O₃ deposition was performed using trimethyl aluminum (TMA) as the organometallic precursor. In a given ALD cycle, the substrate surface was first saturated with the precursor at 80° C. for 4 minutes at 10⁻³ torr. The ALD chamber was then evacuated to remove unadsorbed TMA. In a second half-cycle, a 3 minute pulse of deionized water at 10⁻³ torr was then introduced to the ALD chamber, thereby hydrolyzing the adsorbed trimethyl aluminum at the substrate surface and producing an alumina monolayer having reactive hydroxyl surface groups. This procedure represents one ALD cycle where the film thickness obtained after each cycle was approximately 0.06 nm. Coupons were removed from the ALD chamber after every ten cycles for a total of 70 ALD cycles. Eight coupons per example below represent 0, 10, 20, 30, 40, 50, 60, and 70 ALD cycles, respectively.

### Analysis

The coupons were then characterized by X-ray photoelectron spectroscopy (XPS) to measure relative content of Al, Si, and O on the silicon dioxide and Cu surfaces.

### Results

Example 1 (comparison). Example 1 includes 8 sample coupons having a self-assembled monolayer (SAM) disposed on the Cu surface. Hexamethyldisilazane (HMDS) was employed to block the Cu surface. The SAM appeared disordered and contained pin-holes.

The XPS results for the Cu area are shown in FIG. 4. At 0 ALD cycles the baseline concentrations were: oxygen 17% and copper 7%. The relative concentration of oxygen on the Cu surface remained constant up to 40 cycles. At 50 cycles and above, a continuous increase in the surface oxygen concentration was observed on the Cu surface. The signal from the surface Al on Cu was difficult to detect as the significant signal overlap between Cu and Al prevented accurate deconvolution of the peaks.

The XPS results of the Si area are shown in FIG. 5. The baseline concentrations of the Si area at 0 ALD cycles were: oxygen 43%, silicon 29%, and aluminum 2%. The oxygen and aluminum concentrations increased immediately on the silicon surface consistent with the growth of an Al₂O₃ film. In ALD cycles 1-40, the aluminum signal steadily rose while the silicon signal steadily declined.

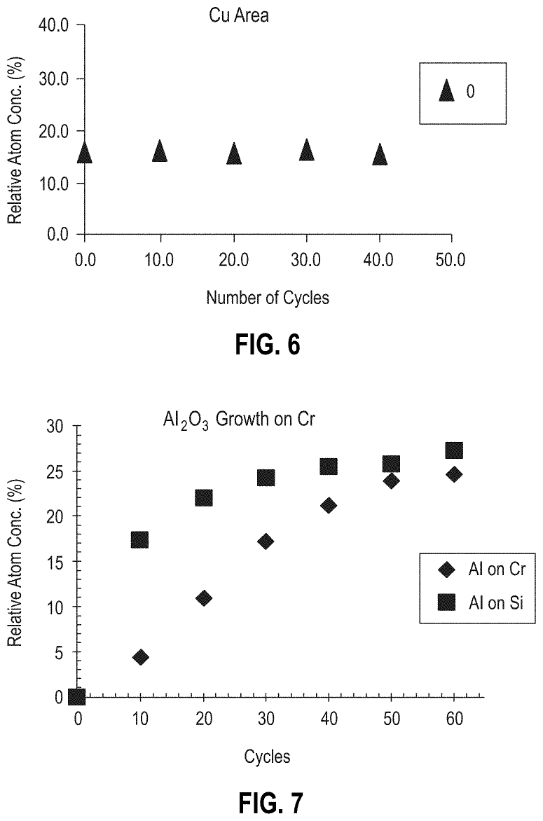

Example 2. The second set of 8 coupons contained no SAM on the copper surface. The XPS results for the Cu area are shown in FIG. 6. The baseline concentration of oxygen of the Cu surface at 0 ALD cycles was approximately 18%. This concentration remained relatively constant up to 40 ALD cycles. These results indicate the native properties of the Cu surface are responsible for inhibiting growth of Al₂O₃ on the Cu surface under these conditions.

Example 3. A third set of 8 coupons used a substrate containing silicon dioxide and chromium surface regions. The ALD was performed as in Example 2 without a SAM. The XPS analysis of the aluminum content on the chromium and silicon dioxide surface regions as a function of number of ALD cycles is shown in FIG. 7. The baseline concentration of oxygen of the chromium surface at 0 ALD cycles was approximately 0%. At 10 ALD cycles, the aluminum content was 18% and 4% on the silicon dioxide and chromium surfaces, respectively. These results indicate that selective growth of Al₂O₃ on the silicon dioxide surface can be maintained for about 1-3 ALD cycles in the presence of chromium under these conditions.

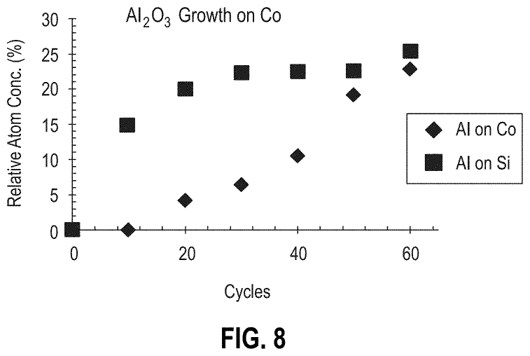

Example 4. A fourth set of 8 coupons used a substrate containing silicon dioxide and cobalt surface regions. The ALD was performed as in Example 2 without a SAM. The XPS analysis of the aluminum content on the cobalt and silicon dioxide surface regions as a function of number of ALD cycles is shown in FIG. 8. The baseline concentration of oxygen of the chromium surface at 0 ALD cycles was approximately 0%. At 10 ALD cycles, the aluminum content was 15% and 0% on the silicon dioxide and cobalt surfaces, respectively. At 20 ALD cycles, the aluminum content was 20% and 4% on the silicon dioxide and cobalt surfaces, respectively. These results indicate that selective growth of Al₂O₃ on the silicon dioxide surface can be maintained for about 10-15 ALD cycles in the presence of chromium under these conditions.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. When a range is used to express a possible value using two numerical limits X and Y (e.g., a concentration of X ppm to Y ppm), unless otherwise stated the value can be X, Y, or any number between X and Y.

The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiments were chosen and described in order to best explain the principles of the invention and their practical application, and to enable others of ordinary skill in the art to understand the invention.

1. A method, comprising:
providing a substrate comprising a silicon dioxide surface and a zero valent metal- containing surface; and
forming a layered structure comprising a layer of alumina selectively disposed on the silicon dioxide surface relative to the metal-containing surface using an atomic layer deposition (ALD) process, the process comprising one or more cycles of i) contacting the silicon dioxide surface and the metal-containing surface of the substrate with an organoaluminum compound at a temperature between 0° C. and 100° C., thereby forming a treated substrate and ii) contacting the treated substrate with water, thereby forming the layered structure.

2. The method of claim 1, wherein said contacting the silicon oxide surface and the metal-containing surface with an organoaluminum precursor is for a period of 1-10 minutes.

3. The method of claim 1, wherein said contacting the treated substrate with water is for a period of 1-10 minutes.

4. The method of claim 1, wherein the organoaluminum precursor is trimethylaluminum.

5. The method of claim 1, wherein said contacting the silicon oxide surface and the metal-containing surface with an organoaluminum precursor is performed at a temperature between 60° C. and 90° C.

6. The method of claim 1, wherein the method further comprises treating the layered structure with a reducing agent.

7. The method of claim 1, wherein the method comprises annealing the layered structure at a temperature above 100° C.

8. The method of claim 1, wherein the metal-containing surface comprises a zero-valent metal selected from the group consisting of copper, chromium, and cobalt.

9. The method of claim 1, wherein the metal-containing surface comprises zero-valent copper.

10. A method, comprising:
providing a database of performed atomic layer deposition (ALD) reactions, the ALD reactions including successes and failures depositing target compositions on different substrate surfaces;
selecting a target composition to be formed by ALD;
selecting a target material on which to selectively deposit the target composition by ALD;
selecting a non-target material on which deposition by ALD of the target composition is not desired;
determining from the database i) common ALD conditions for ALD reactions that form the target composition on the target material and ii) ALD reactions that do not form the target composition on the non-target material; and
depositing the target composition by ALD on a substrate using the common ALD conditions, the substrate comprising i) target surface regions containing the target material and ii) non-target surface regions containing the non-target material, thereby forming a modified substrate comprising the target composition substantially or wholly disposed on the target surface regions.

11. The method of claim 10, wherein the target composition is alumina.

12. The method of claim 11, wherein the target material is silicon oxide.

13. The method of claim 12, wherein the non-target material is a zero-valent metal selected from the group consisting of copper, chromium, and cobalt.

14. The method of claim 13, wherein the ALD conditions include performing the ALD at a temperature between 0° C. and 100° C.

15. The method of claim 10, wherein the ALD conditions exclude a blocking layer on the non-target material during the ALD.

16. The method of claim 10, wherein the non-target material contacts each reactant used to form the target composition during said depositing.

17. A computer program product, comprising a computer readable hardware storage device having a computer-readable program code stored therein, said program code configured to be executed by a processor of a computer system to implement a method comprising:
providing a database of performed atomic layer deposition (ALD) reactions, the ALD reactions including successes and failures depositing target compositions on different substrate surfaces;
selecting a target composition to be formed by ALD;
selecting a target material on which to selectively deposit the target composition by ALD;
selecting a non-target material on which deposition by ALD of the target composition is not desired;
determining from the database common ALD conditions for ALD reactions that form the target composition on the target material and ALD reactions that do not form the target composition on the non-target material; and
depositing the target composition by ALD on a substrate comprising target surface regions containing the target material and the non-target surface regions containing non-target material using the common ALD conditions, thereby forming a modified substrate comprising the target composition substantially or wholly disposed on the target surface regions.

18. A system comprising one or more computer processor circuits configured and arranged to:
provide a database of performed atomic layer deposition (ALD) reactions, the ALD reactions including successes and failures depositing target compositions on different substrate surfaces;
select a target composition to be formed by ALD;
select a target material on which to selectively deposit the target composition by ALD;
select a non-target material on which deposition by ALD of the target composition is not desired;
determine from the database common ALD conditions for ALD reactions that form the target composition on the target material and ALD reactions that do not form the target composition on the non-target material; and
deposit the target composition by ALD on a substrate comprising target surface regions containing the target material and the non-target surface regions containing non-target material using the common ALD conditions, thereby forming a modified substrate comprising the target composition substantially or wholly disposed on the target surface regions.

19. A method, comprising:
providing a substrate that includes (i) a first portion made of zero-valent copper and (ii) a second portion made of silicon oxide having -OH groups attached thereto;
contacting the first portion and the second portion with a compound that includes aluminum (Al) for a predetermined first period of time at a temperature less than 100° C., thereby forming a treated substrate comprising a layer of aluminum-containing material substantially or wholly disposed on, and bound to, the second portion of the substrate, the compound being substantially non-reactive with the copper during the first period;
removing any of the compound that is not bound to the treated substrate;
introducing water to the treated substrate for a predetermined second period, thereby forming an Al₂O₃ layer substantially or wholly disposed on the second portion; and
repeating the steps of contacting, removing, and introducing a given number of times, thereby forming additional layers of Al₂O₃ over the second portion of the substrate, wherein said given number is selected to avoid build-up of Al-containing compounds on the first portion of the substrate.

20. The method of claim 19, wherein the method is carried out at a temperature between 60° C. and 90° C.

21. The method of claim 19, further comprising densifying the additional layers through an annealing process.

22. The method of claim 19, wherein the method comprises contacting the water-treated substrate with a reducing agent, thereby reducing any oxidized copper of the first portion to a zero-valent copper.

23. The method of claim 22, wherein said contacting the water treated substrate with a reducing agent increases etch resistance of the Al₂O₃ layer.

24. A layered structure formed by the method of claim 19, the layered structure comprising a substrate having a surface comprising (i) a first portion made of zero-valent copper and (ii) a second portion comprising one or more layers of Al₂O₃ disposed on silicon oxide.

25. The layered structure of claim 24, wherein the layered structure is a sacrificial etch mask in a lithography process.

26. The layered structure of claim 24, wherein the layered structure is a material component in a semiconductor device.
